(19) United States
(12) Patent Application Publication
(10) Pub. No.: US 2020/0252299 A1
(43) Pub. Date: Aug. 6, 2020

(54) INSTALLING AN APPLICATION CONTROL NETWORK BY USING AN AUTOMATICALLY DETERMINED TOPOLOGY

(71) Applicant: SIGNIFY HOLDING B.V., EINDHOVEN (NL)

(72) Inventors: Bjorn Christiaan Wouter KAAG, EINDHOVEN (NL); Uwe CHITTKA, EINDHOVEN (NL)

(21) Appl. No.: 16/758,284

(22) PCT Filed: Oct. 19, 2018
(86) PCT No.: PCT/EP2018/078672

§ 371 Date: Apr. 22, 2020

(30) Foreign Application Priority Data
Oct. 27, 2017 (EP) 17198733.2

(51) Int. Cl. H04L 12/24; G06F 30/18

(52) U.S. Cl. CPC H04L 41/145; H04L 41/0826; G06F 30/13; G06F 30/18; H04L 41/12

(57) ABSTRACT

A method of installing an application control network comprises using a computer to determine spatial locations of data forwarding devices (81-87; 89) in a spatial area (31), connection information indicating how application devices (41-49, 51-56, 61-68) It and the data forwarding devices (81-87; 89) should be connected by cables and interconnection information indicating how the data forwarding devices (81-87; 89) should be interconnected by cables. Preferably, the spatial area is a floor (31) with six offices (33-35 and 38-39), one conference room (37) and one hallway (36). The method involves determining which of the application devices (41-49, 51-56, 61-68) to connect to the same data forwarding device (81-87; 89) while taking into account a plurality of weighted criteria, at least one of the criteria specifying spatial locations of the application devices (41-49, 51-56, 61-68) in the spatial area (31) and at least one of the criteria relating to connectivity requirements of the application devices (41-49, 51-56, 61-68). The method further comprises placing the data forwarding devices (81-87; 89) at the determined spatial locations and (inter)connecting the data forwarding devices (81-87; 89) and the application devices (41-49, 51-56, 61-68) according to the determined connection and interconnection information. Said application devices (41-49, 51-56, 61-68) may comprise sensors (e.g. motion sensors) and actuators (e.g. lights). The application control network may be a lighting control network. Said connectivity requirements may be specified in an interaction model like an application control plan. In the example, the assignment algorithm has been configured to assign three or four application devices to each data forwarding device (until there are less than three application devices that still need to be assigned) to balance the costs of data forwarding devices against the cost of cabling. Preferably, the models/types of the data forwarding devices are chosen in such a way that data forwarding devices (86 and 87) have more ports than data forwarding devices (81-87; 89).

### FIELD OF THE INVENTION

The invention relates to a method of installing an application control network.

The invention also relates to a computer program product for a computer system enabling such a method to be performed.

### BACKGROUND OF THE INVENTION

Often, networks are designed manually by the company or person installing the network. This also applies to application control networks that comprise sensors and actuators. This can be a laborious process, because it is likely that the initial design contains errors, which need to be corrected. Furthermore, the result is often that more ports are left unused than necessary, because the installer wants to accommodate future extensions of the network.

Automation and design of communication networks capable of handling variations in network traffic is known for example from International patent application WO2016/083841 A1 and U.S. Pat. No. 6,404,744 B1.

Automation of sensor placement is known for example from U.S. patent application U.S.2017/0076015 A1 which discloses a method and apparatus for deploying sensors in a predefined space using a building information model (BIM). U.S.2017/0076015 A1 discloses a method for automatically and effectively deploying lighting sensor into building models. The automatic sensor deployment does not require designers to reference datasheets and/or follow placement guidelines. Instead the guidelines are built-into the tool (e.g. software or device). Optimal locations for sensor placement are identified by solving an optimization problem within the BIM subject to constraints such as 1) sensor functions and 2) shape of sensor coverage area.

Automatic generation of a network topology helps an installer install an application control network. WO2016/154321A1 discloses automatically determining where to place sensors based on a floor plan description. The optical component placement is obtained based on a tradeoff between the bill of material/cost and the detection performance. WO2016/154321A1 does not, however, disclose automatically determining where to place data forwarding devices, e.g. network switches, and how to connect sensors to data forwarding devices. WO2016/154321A1 discloses estimating the cost of wiring by calculating the distance from all the wired components to a central panel to estimate the amount and type of wiring necessary to support panel-to-component communications and powering requirements, but this does not provide any insight in how to create a realistic network topology. Connecting all the wired components directly to a central panel is not realistic in most environments.

### SUMMARY OF THE INVENTION

It is a first object of the invention to provide a method of installing an application control network, which allows use of multiple data forwarding devices and does not require the spatial locations of these data forwarding devices to be manually determined.

In a first aspect of the invention, the method comprises using a computer to read a building plan specifying the preferred spatial location of application devices and an application control plan specifying interaction between said application devices and to determine spatial locations of data forwarding devices in a spatial area, connection information indicating how application devices and said data forwarding devices should be connected by cables and interconnection information indicating how said data forwarding devices should be interconnected by cables by determining which of said application devices to connect to the same data forwarding device while taking into account a plurality of weighted criteria, at least one of said criteria specifying spatial locations of said application devices in said spatial area and at least one of said criteria relating to connectivity requirements of said application devices, placing said data forwarding devices at said determined spatial locations of said data forwarding devices, connecting said data forwarding devices and said application devices according to said determined connection information, and interconnecting said data forwarding devices according to said determined interconnection information. Said application devices may comprise sensors (e.g. motion sensors) and actuators (e.g. lights), for example. The application control network may be a lighting control network, for example. The at least one of said criteria relating to connectivity requirements of said application devices may specify said connectivity requirements, for example. Said connectivity requirements may be specified in an interaction model like the application control plan, for example.

The inventors have recognized that for most building projects, especially when building or refurbishing office buildings, multiple data forwarding devices are required in order to interconnect the application devices and that determining the spatial locations of these data forwarding devices and the (inter)connection information can be automated. This is realized by determining which of the application devices to connect to the same data forwarding device while taking into account the afore-mentioned plurality of weighted criteria.

Aspects of the building structure relevant to said spatial area, such as a building features or constraints resulting from the building architecture for the network placement and/or routing, may be taken into account when determining which of said application devices to connect to the same data forwarding device. By taking into account these architectural aspects, it may be possible to reduce the costs of the application control network by, for example, reducing the number of walls through which cables need to pass, especially walls which are expensive to pass.

One or more of said criteria may influence capital expenditure (Capex) and/or one or more of said criteria may influence operational expenditure (Opex). This helps reduce the costs of the application control network.

One or more of said one or more criteria influencing operational expenditure may represent a time period in which an application device is likely to communicate data. When all application devices connected to a certain data forwarding device only communicate data in the same limited time period (e.g. during working hours), the data forwarding device can be put in sleep mode during this limited time period, thereby saving (energy) costs.

One or more of said one or more criteria influencing capital expenditure may influence costs of said data forwarding devices and/or costs of connecting said application devices and said data forwarding devices. This may include costs of purchasing, leasing or renting data forwarding devices, of cabling and of installing cabling, for example. These costs contribute significantly to the costs of the application control network.

The method may further comprise using said computer to determine a graph of first interconnections between a first group of data forwarding devices, analyze said graph and add at least one further interconnection to said first interconnections based on said analysis. This helps improve the robustness of the application control network.

The method may further comprise adding at least one further data forwarding device to said group of data forwarding devices. Adding a data forwarding device may sometimes be beneficial, e.g. when the robustness can be further increased and this benefit outweighs the costs of the additional data forwarding device.

Analyzing said graph may comprise determining how to improve a metric of the algebraic connectivity of said graph. The algebraic connectivity is a good measure of the robustness of a network.

Analyzing said graph may comprise determining a Fiedler vector of said graph, said Fiedler vector comprising a value for each of said data forwarding devices, and determining which data forwarding devices represented in said graph should be connected to improve said metric of said algebraic connectivity of said graph based on the differences, e.g. squared differences, between said values in said Fiedler vector. This is a computationally simple manner of determining which data forwarding devices to connect to optimally increase robustness of the network. Determining which data forwarding devices represented in said graph should be connected may comprise determining for which two of said data forwarding devices a difference, e.g. squared difference, in corresponding values in said Fiedler vector is largest.

Determining which data forwarding devices represented in said graph should be connected to improve said metric of said algebraic connectivity of said graph may comprise determining which data forwarding devices have at least one network port available and determining for which two of said determined data forwarding devices a squared difference in corresponding values in said Fiedler vector is largest. This is a computationally simple manner of determining which data forwarding devices to connect to optimally increase robustness of the network. Alternatively, data forwarding devices without a network port available might not be excluded and if a data forwarding device without a network port available is selected, an additional data forwarding device may be added or less application devices may be assigned to the selected data forwarding device.

The method may further comprise the computer-implemented steps of validating said spatial locations of said data forwarding device, said connection information and said interconnection information by emulating or simulating said application control network based on the application control plan. This allows the automatically designed topology to be verified using additional information not captured and/or capturable in criteria. If necessary, the user of the computer may then request the computer to automatically create a new topology, preferably with adapted inputs.

The method may further comprise the computer-implemented steps of comparing a first network topology with a second network topology, said first network topology comprising said spatial locations of said data forwarding devices, said connection information and said interconnection information, and analyzing differences between said first network topology and said second network topology. The analysis may be presented to the user of the computer, for example, thereby allowing the user to easily check the most important differences between the two topologies and if necessary, request the computer to automatically create a new topology, preferably with adapted inputs.

Which of said application devices communicates with which other one or more of said application devices may also be taken into account when determining which of said application devices to connect to the same data forwarding device. When application devices that communicate with each other can be connected to the same data forwarding device, this may reduce the network load.

Moreover, a computer program for carrying out the methods described herein, as well as a non-transitory computer readable storage-medium storing the computer program are provided. A computer program may, for example, be downloaded by or uploaded to an existing device or be stored upon manufacturing of these systems.

A non-transitory computer-readable storage medium stores at least one software code portion, the software code portion, when executed or processed by a computer, being configured to perform executable operations comprising: determining spatial locations of data forwarding devices in a spatial area, connection information indicating how application devices and said data forwarding devices should be connected by cables and interconnection information indicating how said data forwarding devices should be interconnected by cables by determining which of said application devices to connect to the same data forwarding device while taking into account a plurality of weighted criteria, at least one of said criteria specifying spatial locations of said application devices in said spatial area and at least one of said criteria relating to connectivity requirements of said application devices.

Program code embodied on a computer readable medium may be transmitted using any appropriate medium, including but not limited to wireless, wireline, optical fiber, cable, RF, etc., or any suitable combination of the foregoing. Computer program code for carrying out operations for aspects of the present invention may be written in any combination of one or more programming languages, including an object-oriented programming language such as Java(™), Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems), and computer program products according to embodiments of the present invention. It will be understood that each block of the flowchart illustrations and/or block diagrams, and combinations of blocks in the flowchart illustrations and/or block diagrams, can be implemented by computer program instructions. These computer program instructions may be provided to a processor, in particular a microprocessor or a central processing unit (CPU), of a general purpose computer, special purpose computer, or other programmable data processing apparatus to produce a machine, such that the instructions, which execute via the processor of the computer, other programmable data processing apparatus, or other devices create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the figures illustrate the architecture, functionality, and operation of possible implementations of devices, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

### BRIEF DESCRIPTION OF THE DRAWINGS

These and other aspects of the invention are apparent from and will be further elucidated, by way of example, with reference to the drawings, in which:

FIG. 1 is a flow diagram of an embodiment of the method of the invention;

FIG. 2 is a block diagram of an example application control network;

FIG. 3 shows an example of a floor plan of a building and locations of application devices;

FIG. 4 depicts the search order used for assigning the application devices of FIG. 3 to data forwarding devices;

FIG. 5 shows data forwarding devices and assignments of the application devices of FIG. 3 to these data forwarding devices;

FIG. 6 shows six selected interconnections in star topology between the data forwarding devices of FIG. 5;

FIG. 7 shows a graph of the data forwarding devices and the interconnections of FIG. 6;

FIG. 8 shows six selected interconnections in ring topology between the data forwarding devices of FIG. 5;

FIG. 9 shows a graph of the data forwarding devices and the interconnections of FIG. 8;

FIG. 10 is a flow diagram of an embodiment of one of the steps of FIG. 1;

FIG. 11 shows six selected interconnections in ring topology and three potential interconnections between the data forwarding devices of FIG. 5 in a graph;

FIG. 12 is a flow diagram of an embodiment of one of the steps of FIG. 10;

FIG. 13 is a flow diagram of an embodiment of one of the steps of FIG. 12;

FIG. 14 shows the six selected interconnections of FIG. 11 and selection of one of the potential interconnections of FIG. 11;

FIG. 15 shows a graph of the data forwarding devices and the interconnections of FIG. 14;

FIG. 16 shows the seven selected interconnections of FIG. 14 plus one additional interconnection;

FIG. 17 shows a graph of the data forwarding devices and the interconnections of FIG. 16;

FIG. 18 shows the floor plan and application devices of FIG. 3, but in which no connections are allowed through one of the walls;

FIG. 19 shows interconnections between the application devices and data forwarding devices of FIG. 18 which take into account the wall of FIG. 18; and

FIG. 20 is a block diagram of an exemplary data processing system for enabling the method of the invention to be performed.

Corresponding elements in the drawings are denoted by the same reference numeral.

### DETAILED DESCRIPTION OF THE EMBODIMENTS

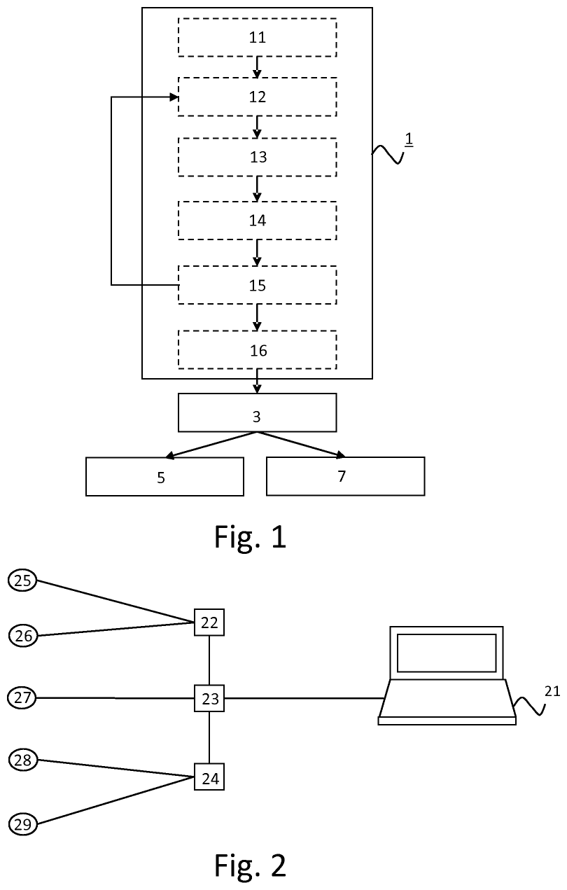

An embodiment of the method of the invention is shown in FIG. 1. A step 1 comprises using a computer to determine spatial locations of data forwarding devices (e.g. switches) in a spatial area, connection information indicating how application devices (e.g. sensors and actuators) and the data forwarding devices should be connected by cables (these connections are also referred to as “end links”) and interconnection information indicating how the data forwarding devices should be interconnected by cables (these interconnections are also referred to as “interlinks”). This determination is made by determining which of the application devices to connect to the same data forwarding device while taking into account a plurality of weighted criteria, at least one of the criteria specifying spatial locations of the application devices in the spatial area and at least one of the criteria relating to connectivity requirements of the application devices

A step 3 comprises placing the data forwarding devices at the determined spatial locations of the data forwarding devices. A step 5 comprises connecting the data forwarding devices and the application devices according to the determined connection information. A step 7 comprises interconnecting the data forwarding devices according to the determined interconnection information. The computer may be a personal computer, a laptop, an industrial handheld computer, a tablet, a workstation, a server or a single-board computer such as a Raspberry Pi, for example.

In the embodiment of FIG. 1, step 1 comprises six sub steps: steps 11 to 16. Step 11 comprises reading a building plan and an application control plan. The building plan is analyzed to collect coordinates defining spaces, preferably per floor. In addition to the geometry of the building, the building plan provides information on the number of sensors and actuators and their preferred location or a rough estimate thereof The computer also reads a rudimentary application control plan describing the preferred application scenes what messages from sensors will cause one or more actuators to change state. As an example, an actuator may be a light that is switched on/off/dimmed upon a particular sensor event.

Step 12 comprises determining an initial version of the spatial locations of the data forwarding devices, the connection information indicating how the application devices and the data forwarding devices should be connected by cables and the interconnection information indication how the data forwarding devices should be interconnected by cables. Data forwarding devices are placed and connected to application devices and to each other on the basis of balanced weight criteria. An optimal spatial location is selected for every data forwarding device. The location of a data forwarding device may depend on conflicting criteria such as device cost, #ports, breach cost, location of nearby cable trays, etc. which are balanced. The data forwarding device ports are optimally filled with application devices and other data forwarding devices. Since the network design has complete overview of the whole installation, the port usage on a data forwarding device can be optimized. Optimal interconnections between the data forwarding devices and optimal connections between the application devices and the data forwarding devices are created covering multiple requirements, such as e.g. cable cost, hourly tariffs of installer, nearby cable trays, cost to breach walls, etc.

Step 13 comprises an optional but advantageous step of adding redundant interconnections between data forwarding devices to improve robustness. Graph algorithms such as e.g. the algebraic connectivity optimization (ACO) according to Fiedler is applied to increase redundancy of the network. By adding additional cables and (optionally) data forwarding devices for redundancy it is prevented that the failure or destruction of single cables will lead to loss of control over parts of the application control network, e.g. lighting control installation.

Step 14 comprises an optional but advantageous step of adding bypass interconnections between data forwarding devices to optimize for an application specific requirement, for example to reduce power consumption. By adding additional cables and (optionally) data forwarding devices, more alternative communication paths are created. This will prevent that certain parts of the network topology are always on and cannot enter a low(er) power state. Although FIG. 1 shows step 14 being performed after step 13, steps 13 and 14 may be performed in parallel or step 13 may be performed after step 14 in an alternative embodiment.

Step 15 comprises an optional but advantageous step of validating the resultant topology with real data traffic. The computer checks if the application control plan can be executed and may compare key performance parameters between the automatically generated network topology and an alternative design.

The above steps 12-15 may be repeated until a satisfactory result is achieved, which may be defined using thresholds on the network attributes, or calculated metrics.

Step 16 comprises outputting the automatically generated network topology, i.e. the locations of the data forwarding devices, the connection information and the interconnection information. The computer may draw the topology as an overlay on the building plan, a schematic system diagram or as lists and plans. The computer may also generate information for a Bill of Material, an offer, etc.

FIG. 2 shows an example of an installed application control network. Application devices 25-29 are connected to data forwarding devices 22-24 via network cables. The application devices 25-29 comprise one or more sensor devices, e.g. devices detecting heat and/or motion, and one or more actuator devices, e.g. lights. A control system 21 is connected to data forwarding device 23 via a network cable. The control system 21 may comprise control software running on a computer (i.e. may be software defined), for example. The control system 21 reads the application control plan and uses the application scenes stipulated therein to dynamically configure communication paths between application devices. For example, the data forwarding device 22 may be configured to forward data it receives from application device 25 to application device 29. The application devices 25-29 may receive power from the data forwarding devices 22-25, e.g. using Power over Ethernet (PoE) technology. Alternatively, one or more of the application devices 25-29 may receive power from a different energy source (not shown).

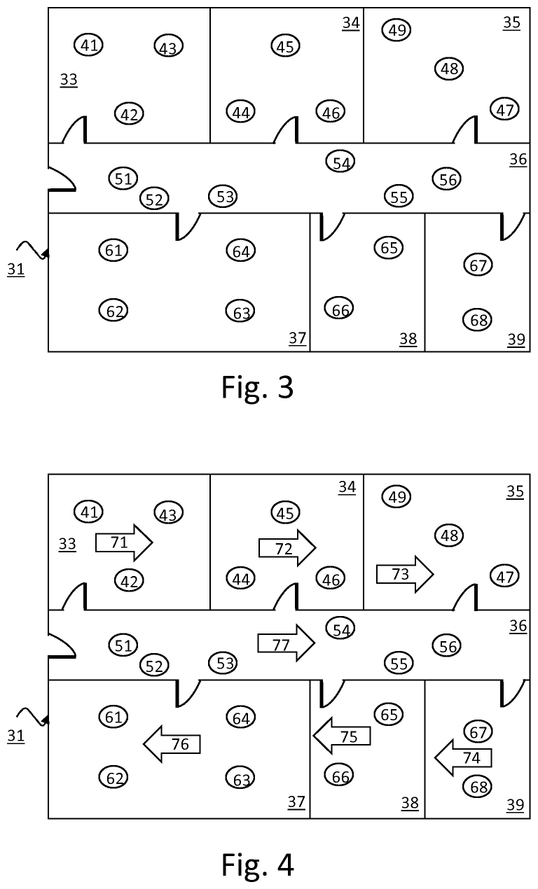

FIG. 3 shows an example of a building plan of a representative office, which is assumed to be read in step 11 in the following description. This example building plan is of a standard office, but building plans of other types of offices may be used as well. The building plan of FIG. 3 depicts a floor 31 with six offices 33-35 and 38-39, one conference room 37 and one hallway 36. The building plan of FIG. 3 further depicts application devices 41-68, such as actuators (e.g. lights) and/or sensors (e.g. Passive InfraRed/PIR presence detectors). In FIG. 3, the spaces (i.e. the rooms and the hallway) have different application scenes. Offices 33-35 and 37-38 have an automated dimming control of the lights that will switch the lights off or will dim them to a lower intensity. Offices 33-35 and 37-38 are spaces where people will walk in and out frequently, causing the sensors to dim the light levels and switch the lights off after a period of inactivity in the particular space. Hallway 36 is constantly lit and is not to be switched off at all. Conference room 37 is not frequently used and light levels are switched off for most of the time.

In step 12, application devices 41-68 are assigned to data forwarding devices and the locations of data forwarding devices and of cables linking these data forwarding devices with the application devices 41-68 and interconnecting these data forwarding devices are determined. As previously described, this determination is made while taking into account a plurality of weighted criteria and at least one of the criteria relates to spatial locations of the application devices in the spatial area and at least one of the criteria relates to connectivity requirements of the application devices. The one or more criteria that relate to connectivity requirements of the application devices may use information specifying which of the application devices communicates with which other one or more of the application devices so that these application devices are preferably assigned to the same data forwarding device.

The following are examples of other criteria that may be taken into account when determining which of the application devices to connect to the same data forwarding device and which data forwarding devices to interconnect:
one or more criteria relating to architectural aspects of (physical structures in) the spatial area;
one or more criteria influencing capital expenditure; and
one or more criteria influencing operational expenditure.

One criterion that influences the capital expenditure of the application network is the cost of connecting the application devices and the data forwarding devices and interconnecting the data forwarding devices. Shorter cables can save cost, but minimizing cable length could lead to (inter)connections that reduce the amount of power consumption reduction or make it impossible to reduce power consumption. Furthermore, the costs of establishing a wired connection between devices through a wall should be taken into account, because it may be cheaper to add one or more additional data forwarding devices and/or one or more additional cables than establishing a wired connection though a certain wall. Another criterion factor that influences the capital expenditure of the application network is the cost of the data forwarding devices. The costs of the data forwarding devices depend on the number of data forwarding devices to be installed, but also on the number of ports on a data forwarding device. Other criteria may be installation cost of a data forwarding device, where a budget for providing a connection to the main power grid may be taken into account and time to install the data forwarding device on location, for example.

One criterion that influences the operational expenditure of the application network is represented by a time period in which an application device is likely to communicate data. This criterion influences the costs of electrical energy consumed by the data forwarding devices. A data forwarding device can enter a low power state or even switch off entirely when none of the application devices connected to this data forwarding device is active. As soon as at least one application device demands power from a data forwarding device or needs to transmit or receive data via this data forwarding device, this data forwarding device cannot enter the low power state. The time periods are determined based on information specifying in which time periods the application devices are likely to communicate data. This information is derived from the application control plan in this embodiment. The time periods may be as coarse as being a choice between 12 hours per day or 24 hours per day to make it easier to estimate the costs, or another time period.

These time periods are preferably taken into account when assigning application devices to data forwarding devices. This is especially advantageous if data forwarding devices can be switched to low power mode, but individual ports of data forwarding devices cannot be switched to low power mode. Since the hallway 36 needs to be constantly lit (all day and every day), assigning lights in the hall (e.g. application devices 51-56) to data forwarding devices together with the application devices in the offices 33-36 would mean that all these data forwarding devices cannot switch to low power mode, even if most of the connected application devices are not in use in the evening and in weekends. Assigning only application devices 51-56 in the hallway 36 to the same data forwarding devices is therefore beneficial.

An optimization algorithm may be used to determine which application device to connect to which data forwarding device using the weighted criteria. The same criteria or (partially) different criteria may be used to determine which data forwarding devices to interconnect. A value may be calculated for each of a plurality of possible topology designs, for instance. A parameter may be multiplied with a weight for each criterion and the value may be calculated as the sum of these multiplications, for example. Local search or global search algorithms may be used as optimization algorithm, e.g. to find a local minimum value or the global minimum value.

When a local search algorithm is used, application devices may be assigned to data forwarding devices one by one and per data forwarding device, for example. In this case, it may be determined for each application device how much the value would increase if this application device would be connected to the current data forwarding device. The following are examples of parameters that may be multiplied with weights:
The spatial distance of the current data forwarding device to the application device being assessed
The number of walls that have be passed to connect the current data forwarding device to the application device being assessed.
If the application devices have one of two different operations times (e.g. 12 h, 24 h): the required change of the operation time of the current data forwarding device to link the application device being assessed.

The weighted sum of these three multiplications has to be evaluated for each candidate application device taking to account the application devices that have already been assigned to the current data forwarding device and the candidate application device with the lowest value is assigned to the current data forwarding device. When the maximum number of ports is occupied on the current data forwarding devices, the assignment of the applications devices to the data forwarding devices is accepted and the position of the current data forwarding device is determined to be the average position of the assigned application devices. It is possible to enhance this process by limiting the acceptable value of the weighted sum (per application device or per data forwarding device) and by permitting that one port of the data forwarding device is not occupied if the weighted sum would exceed this limit. This causes less cluster fragmentation.

The first application device may be assigned to the first data forwarding device without applying the above criteria, but by starting with an application device at an edge of the building to avoid an irregular/fragmented clustering. The first application device of the next data forwarding devices may be selected, for example, based on the distance of the candidate (i.e. unassigned) application devices to the previous data forwarding and to the outer walls (to avoid chaotic search paths), but other criteria may also be taken into account. A preference for a certain search direction (e.g. clockwise or counterclockwise) may be pre-defined or may be determined based on the shape of the building, for example.

The process described above already makes it possible to achieve a quite reasonable low-level clustering for small floor plans. The stability of this process can be increased by the use of global optimization schemes like simulated annealing to find optimums for the weighted criteria and by an explicit incorporation of constraints that suppresses unwanted topologies, e.g. those with fragmented clusters. In this case, the distance from the outer walls can be incorporated as criterion to avoid chaotic search paths.

FIG. 4 shows the application devices 41-68 being assigned to data forwarding devices in the order shown by arrows 71-77. First, the application devices 41-43 in office 33 are assigned to data forwarding devices, then application devices 44-46 in office 34 are assigned to data forwarding devices, etc. Different orders than the one shown in FIG. 4 may alternatively be used, as described above. One example is to group all application devices belonging to the same or similar application control scenes, as stipulated in the initial application control plan, to the same data forwarding device. This means grouping based on identical weighted criteria that are regarded as more important. As an example, “always on” application devices could be assigned to one data forwarding device and the application devices that are not always on could be assigned to another data forwarding device, and so forth.

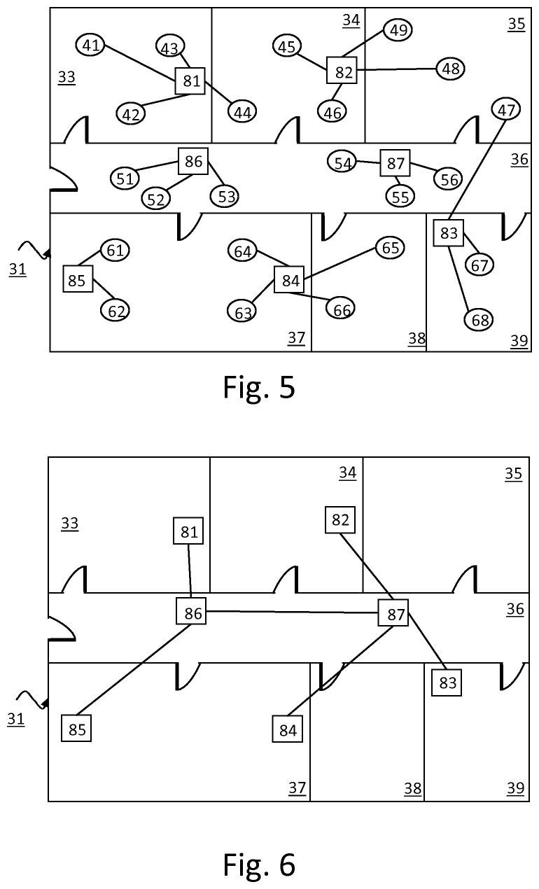

An example of an assignment of the application devices 41-68 to data forwarding devices, i.e. of the end links, is shown in FIG. 5. One way of interconnecting data forwarding devices is in a star(-like) topology. As a result, the data forwarding devices that are the center of a star need more ports for connecting to other data forwarding devices than the data forwarding devices that are not. In the example of FIG. 5, the assignment algorithm has been configured to assign three or four application devices to each data forwarding device (until there are less than three application devices that still need to be assigned) to balance the costs of data forwarding devices against the cost of cabling. Preferably, the models/types of the data forwarding devices are chosen in such a way that data forwarding devices 86 and 87 have more ports than data forwarding devices 81-85.

With 23 application devices and three to four application devices per data forwarding device, six data forwarding devices might have been sufficient. However, by assigning only application devices in the hallway 36, i.e. application devices 51-56, to the same data forwarding devices, i.e. data forwarding devices 86-87, seven data forwarding devices are necessary. In this case, the cost saved by the resulting power consumption reduction outweighs the cost of an additional data forwarding device. FIG. 6 shows the data forwarding devices 81 to 87 being connected, i.e. the interlinks, in a star-like topology.

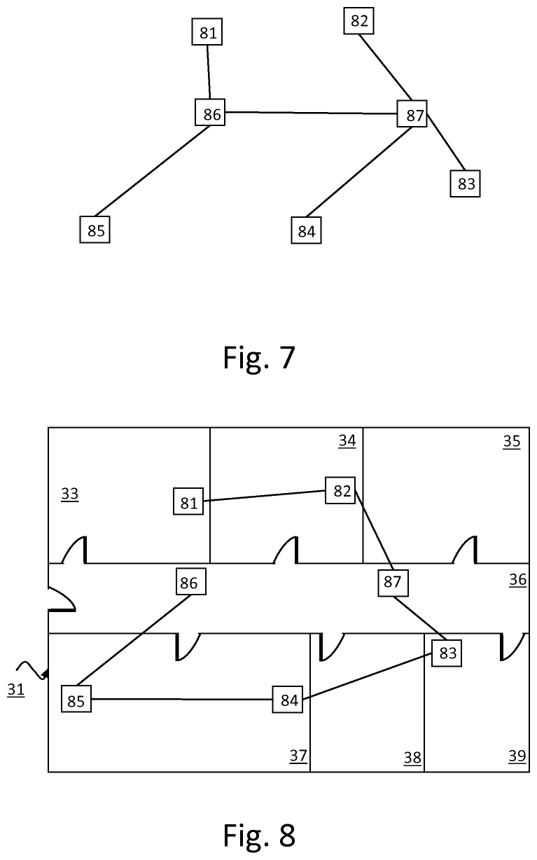

Steps 13 is intended to improve the robustness of the application control network and step 14 may improve the robustness of the application control network as well. If a connection, e.g. a connector or a cable, between two data forwarding devices is damaged and someone needs to come and repair the connection urgently, this may result in a significant increase in the costs of the application control network. It is therefore beneficial to ensure that the application control network is robust against damaged connections between data forwarding devices. One way of determining the robustness of the interconnections between the data forwarding devices is to represent them in a graph and determine the algebraic connectivity of this graph. FIG. 7 shows a graph that was made for the interconnections between the data forwarding devices of FIG. 6.

The algebraic connectivity (also known as Fiedler value or Fiedler eigenvalue) of a graph is the second-smallest eigenvalue of the Laplacian matrix of this graph. The Laplacian matrix (L) is defined as defined as: L=D−A, where D is the degree matrix and A is the adjacency matrix of the graph (the first column and row relate to data forwarding device 81, the second column and row relate to data forwarding device 82, etc.). The

Laplacian matrix of the graph shown in FIG. 7 is:

$$( [ \begin{matrix}1 & 0 & 0 & 0 & 0 & 0 & 0 \\ 0 & 1 & 0 & 0 & 0 & 0 & 0 \\ 0 & 0 & 1 & 0 & 0 & 0 & 0 \\ 0 & 0 & 0 & 1 & 0 & 0 & 0 \\ 0 & 0 & 0 & 0 & 1 & 0 & 0 \\ 0 & 0 & 0 & 0 & 0 & 3 & 0 \\ 0 & 0 & 0 & 0 & 0 & 0 & 4\end{matrix} ] - [ \begin{matrix}0 & 0 & 0 & 0 & 0 & 1 & 0 \\ 0 & 0 & 0 & 0 & 0 & 0 & 1 \\ 0 & 0 & 0 & 0 & 0 & 0 & 1 \\ 0 & 0 & 0 & 0 & 0 & 0 & 1 \\ 0 & 0 & 0 & 0 & 0 & 1 & 0 \\ 1 & 0 & 0 & 0 & 1 & 0 & 0 \\ 0 & 1 & 1 & 1 & 0 & 0 & 0\end{matrix} ] ) = [ \begin{matrix}1 & 0 & 0 & 0 & 0 & - 1 & 0 \\ 0 & 1 & 0 & 0 & 0 & 0 & - 1 \\ 0 & 0 & 1 & 0 & 0 & 0 & - 1 \\ 0 & 0 & 0 & 1 & 0 & 0 & - 1 \\ 0 & 0 & 0 & 0 & 1 & - 1 & 0 \\ - 1 & 0 & 0 & 0 & - 1 & 3 & 0 \\ 0 & - 1 & - 1 & - 1 & 0 & 0 & 4\end{matrix} ]$$

The calculation of eigenvalues of a matrix is well known. The algebraic connectivity of this graph is 0.2679. The Fiedler vector, i.e. the eigenvector corresponding to the Fiedler eigenvalue, is [−0.6280, 0, 0, 0, −0.6280, −0.4597, 0].

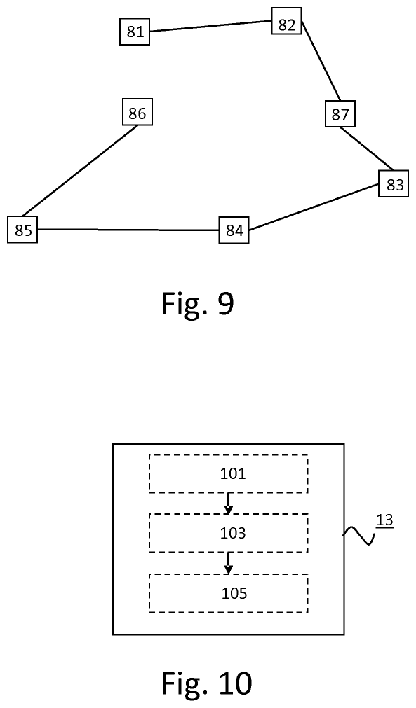

The algebraic connectivity, and therefore the robustness of the application control network, can be improved by using a ring topology instead of a star(-like) topology. FIG. 8 shows interconnections between the data forwarding devices of FIG. 5 in a topology that resembles an unfinished ring. The same number of interconnections between data forwarding devices is used in the network of FIG. 8 as in the network of FIG. 6. Although the algebraic connectivity of the network of FIG. 6 is higher than that of FIG. 8, adding an additional interconnection to the network of FIG. 8, i.e. creating a ring, results in a higher algebraic connectivity than adding an additional interconnection to the network of FIG. 6 would. FIG. 9 shows a graph that was made for the interconnections between the data forwarding devices of FIG. 8. The Laplacian matrix of the graph shown in FIG. 9 is:

$$( [ \begin{matrix}1 & 0 & 0 & 0 & 0 & 0 & 0 \\ 0 & 2 & 0 & 0 & 0 & 0 & 0 \\ 0 & 0 & 2 & 0 & 0 & 0 & 0 \\ 0 & 0 & 0 & 2 & 0 & 0 & 0 \\ 0 & 0 & 0 & 0 & 2 & 0 & 0 \\ 0 & 0 & 0 & 0 & 0 & 1 & 0 \\ 0 & 0 & 0 & 0 & 0 & 0 & 2\end{matrix} ] - [ \begin{matrix}0 & 1 & 0 & 0 & 0 & 0 & 0 \\ 1 & 0 & 0 & 0 & 0 & 0 & 1 \\ 0 & 0 & 0 & 1 & 0 & 0 & 1 \\ 0 & 0 & 1 & 0 & 1 & 0 & 0 \\ 0 & 0 & 0 & 1 & 0 & 1 & 0 \\ 0 & 0 & 0 & 0 & 1 & 0 & 0 \\ 0 & 1 & 1 & 0 & 0 & 0 & 0\end{matrix} ] ) = [ \begin{matrix}1 & - 1 & 0 & 0 & 0 & 0 & 0 \\ - 1 & 2 & 0 & 0 & 0 & 0 & - 1 \\ 0 & 0 & 2 & - 1 & 0 & 0 & - 1 \\ 0 & 0 & - 1 & 2 & - 1 & 0 & 0 \\ 0 & 0 & 0 & - 1 & 2 & - 1 & 0 \\ 0 & 0 & 0 & 0 & - 1 & 1 & 0 \\ 0 & - 1 & - 1 & 0 & 0 & 0 & 2\end{matrix} ]$$

The algebraic connectivity of this graph is 0.1981. The Fiedler vector is [−0.5211, −0.4179, 0, 0.2319, 0.4179, 0.5211, −0.2319].

After determining the initial version of the output locations and the (inter)connection information in step 12, which resulted in the topology of FIG. 8, step 13 is performed. As shown in FIG. 10, step 13 comprises a step 101 of determining a graph of first interconnections between a first group of data forwarding devices, a previously described, and a step 103 of analyzing the graph. Step 13 further comprises a step 105 of adding at least one further interconnection to the first interconnections based on the analysis, e.g. by increasing the algebraic connectivity of the graph (in order to improve the robustness of the application control network). In the application control network of FIG. 8, this means creating a ring.

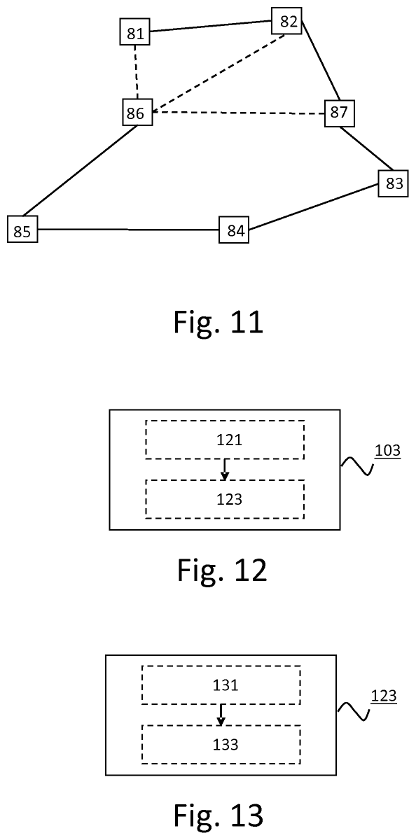

There are several possibilities for adding an additional interconnection between data forwarding devices to the application control network of FIG. 8. Three of these possibilities are depicted in FIG. 11: interconnecting data forwarding devices 86 and 81, interconnecting data forwarding devices 86 and 82, and interconnecting data forwarding devices 86 and 87. In order to choose from these possibilities, step 103 comprises a sub step 121 of determining a Fiedler vector of the graph, the Fiedler vector comprising a value for each of the data forwarding devices, and a sub step 123 of which data forwarding devices represented in the graph should be connected based on the, e.g. squared, differences between the values in the Fiedler vector, see FIG. 12.

There are two options for adding an interlink between two data forwarding devices if at least one of the devices does not have a free port available: As a first option, the algorithm frees up a port on a selected data forwarding device for use by the new interlink and the algorithm repeats the initial step of assigning application devices to data forwarding devices. As a second option, the assignment of application devices to data forwarding devices is left as it is, the ring is opened between two existing data forwarding devices, of which one was selected for forming the ideal additional interlink, an additional new data forwarding device is installed in between the two existing data forwarding devices, and the new data forwarding device will connect an interlink to another point in the network where a similar exercise is repeated. The first option is optimal for a newly planned network and the second option is optimal for an existing network without free ports on data forwarding devices, where laborious reinstalling of cabling should be avoided. The algorithm may help find an ideal solution.

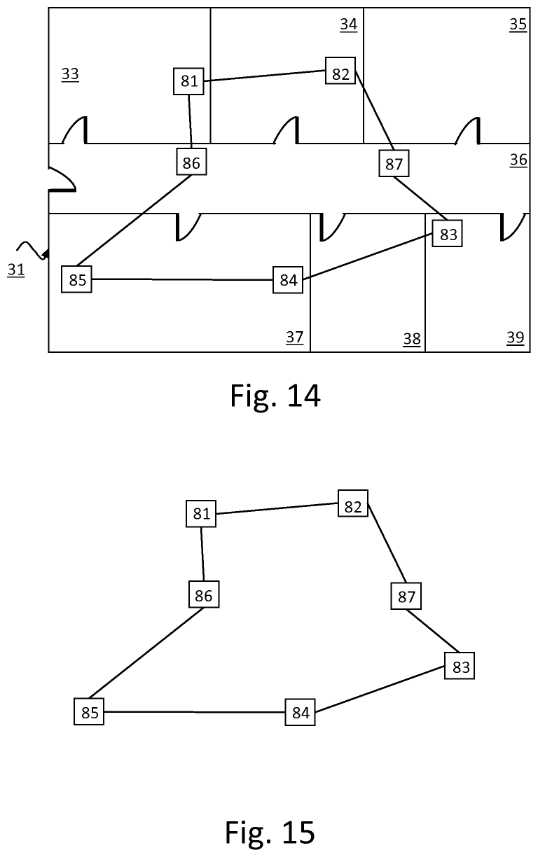

Step 123 comprises a sub step 131 of determining which data forwarding devices have at least one network port available and a sub step 133 of determining for which two of the determined data forwarding devices a squared difference in corresponding values in the Fiedler vector is largest, see FIG. 13. The Fiedler vector of the graph shown in FIG. 9 is [−0.5211, −0.4179, 0, 0.2319, 0.4179, 0.5211, −0.2319]. In the application control network of FIG. 8, all data forwarding devices have at least one network port available. The largest squared difference is between −0.5211 (data forwarding device 81) and +0.5211 (data forwarding device 86). Interconnecting data forwarding device 81 and data forwarding device 86 should, of all the possibilities, therefore result in the largest increase in algebraic connectivity/robustness. This interconnection has been added to the application control network shown in FIG. 14. FIG. 15 shows a graph that was made for the interconnections between the data forwarding devices of FIG. 14. The Laplacian matrix of the graph shown in FIG. 15 is:

$$( [ \begin{matrix}2 & 0 & 0 & 0 & 0 & 0 & 0 \\ 0 & 2 & 0 & 0 & 0 & 0 & 0 \\ 0 & 0 & 2 & 0 & 0 & 0 & 0 \\ 0 & 0 & 0 & 2 & 0 & 0 & 0 \\ 0 & 0 & 0 & 0 & 2 & 0 & 0 \\ 0 & 0 & 0 & 0 & 0 & 2 & 0 \\ 0 & 0 & 0 & 0 & 0 & 0 & 2\end{matrix} ] - [ \begin{matrix}0 & 1 & 0 & 0 & 0 & 1 & 0 \\ 1 & 0 & 0 & 0 & 0 & 0 & 1 \\ 0 & 0 & 0 & 1 & 0 & 0 & 1 \\ 0 & 0 & 1 & 0 & 1 & 0 & 0 \\ 0 & 0 & 0 & 1 & 0 & 1 & 0 \\ 1 & 0 & 0 & 0 & 1 & 0 & 0 \\ 0 & 1 & 1 & 0 & 0 & 0 & 0\end{matrix} ] ) = [ \begin{matrix}2 & - 1 & 0 & 0 & 0 & - 1 & 0 \\ - 1 & 2 & 0 & 0 & 0 & 0 & - 1 \\ 0 & 0 & 2 & - 1 & 0 & 0 & - 1 \\ 0 & 0 & - 1 & 2 & - 1 & 0 & 0 \\ 0 & 0 & 0 & - 1 & 2 & - 1 & 0 \\ - 1 & 0 & 0 & 0 & - 1 & 2 & 0 \\ 0 & - 1 & - 1 & 0 & 0 & 0 & 2\end{matrix} ]$$

The algebraic connectivity of this graph is 0.7530. The Fiedler vector is [0.5345, 0.3282, −0.4844, −0.4787, −0.1126, 0.3383, −0.1253]. If a second additional interconnection should be added, then interconnecting data forwarding device 81 and data forwarding device 83 results in the largest increase in algebraic connectivity/robustness, because the squared difference between 0.5345 and −0.4844 is the largest squared difference (and both have at least one network port available). That the largest squared difference results in the largest increase in algebraic connectivity/robustness is disclosed in “A Distributed Strategy for Near-Optimal Network Topology Design”, Dong Xue et al., International Symposium on Mathematical Theory of Networks and Systems, 7-14, published in 2014, see equitation (5) of chapter III.

If data forwarding device 83 would not have had a network port available, then interconnecting data forwarding device 81 and data forwarding device 84 would result in the largest Increase in algebraic connectivity/robustness. If some or all of the data forwarding devices do not have network ports available for additional interconnections, it may be possible to choose a model/type of data forwarding device with more ports for one or more of the data forwarding devices or to add an additional data forwarding device. In the latter case, step 12 should be repeated (not shown in FIG. 1).

A more robust application control network should normally result in lower maintenance costs, as urgent maintenance is required less often. Thus, the costs of repairing the application control network are estimated to be lower when the determined algebraic connectivity is higher. The determined algebraic connectivity may be translated to a cost estimate in order to compare it with other costs, e.g. the costs of additional connections and data forwarding devices. For example, an algebraic connectivity lower than 0.75 may increase the costs of maintaining the application control network by a certain amount. The algorithm can identify one or more candidate interlinks. Based on additional criteria an optimal selection can be made. The Fiedler algorithm is applied with weighted links. For example, the cost of breaching a wall versus the cable cost to route a cable around said wall or different Opex and/or Capex criteria. Instead of improving the robustness of the application control network by increasing the algebraic connectivity, other algorithms could be applied to increase specifically the node connectivity or the edge connectivity by increasing the number of interconnection, especially if the initial version of the application control network seems to be far from the optimum. In this way, the robustness with respect to data forwarding device failures or with respect to link/cable failures could be specifically addressed. Node connectivity v(G) represents the minimum number of nodes (application devices in this case) that needs to be removed to disconnect the remaining nodes from each other, i.e. to create two separated networks. Edge connectivity η(G) represents the minimum number of edges (cables/interconnections in this case) that need to be removed to disconnect the nodes from each other.

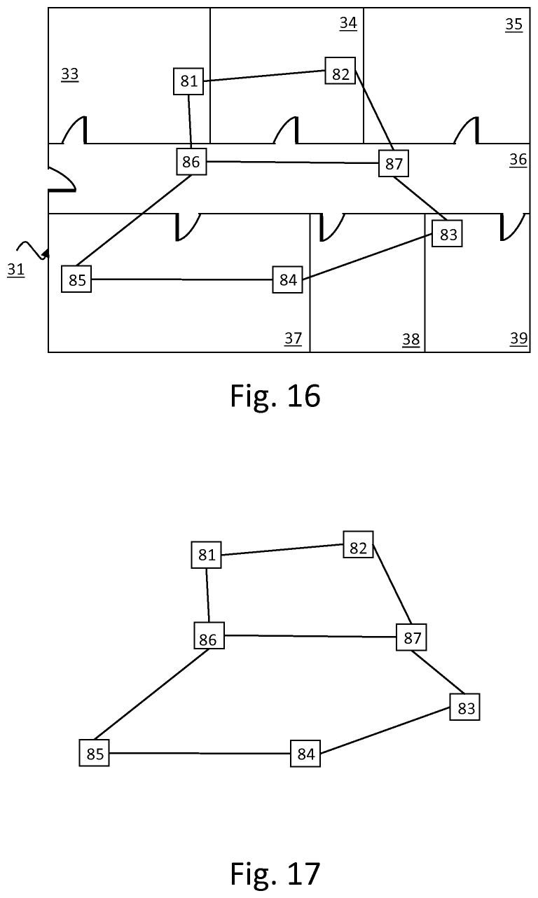

In step 14, one or more further connections between the data forwarding devices is included in the connection information so as to optimize for an application specific requirement. In a general case this is realized by applying certain weights to the corresponding links and increasing the algebraic connectivity of the weighted graph. For example: analyzing further connections in order to reduce the costs of electrical energy consumed by the data forwarding devices if this reduces costs of the application control network. This step increases the bypass options to avoid long paths in certain conditions, which would require that many data forwarding devices must remain under power to transfer messages from a sensor to a controller to an actuator. This is illustrated in FIG. 16, where the application devices apply different power-on criteria than previously described in relation to FIG. 3. An interconnection between data forwarding device 86 and data forwarding device 87 has been added in the application control network of FIG. 16. This is beneficial, for example, when an application device connected to data forwarding device 86 needs to communicate with an application device connected to data forwarding device 87. For instance, application device 56 of FIG. 3 may be a light sensor and application device 51 may be a light source which turns on and off depending on the output of this light sensor instead of the application device 51 being a light source which is always on, which resulted in the application devices 51-56 in the hall 36 being assigned to exclusive data forwarding devices in FIG. 5. Optionally, a further data forwarding device may be added as well in step 14.

By interconnecting data forwarding device 86 and data forwarding device 87, all of the data forwarding devices 81-85 may be switched to a low power state in the evenings and in the weekend. Adding this interconnection is thus advantageous, even though it does not increase the algebraic connectivity of the non-weighted graph, i.e. the robustness of the application control network. However, in other situations, adding an interconnection to reduce power consumption could at the same time increase the algebraic connectivity of the non-weighted graph, i.e. the robustness of the application control network. FIG. 17 shows a graph that was made for the interconnections between the data forwarding devices of FIG. 16. The Laplacian matrix of the graph shown in FIG. 17 is:

$$( [ \begin{matrix}2 & 0 & 0 & 0 & 0 & 0 & 0 \\ 0 & 2 & 0 & 0 & 0 & 0 & 0 \\ 0 & 0 & 2 & 0 & 0 & 0 & 0 \\ 0 & 0 & 0 & 2 & 0 & 0 & 0 \\ 0 & 0 & 0 & 0 & 2 & 0 & 0 \\ 0 & 0 & 0 & 0 & 0 & 3 & 0 \\ 0 & 0 & 0 & 0 & 0 & 0 & 3\end{matrix} ] - [ \begin{matrix}0 & 1 & 0 & 0 & 0 & 1 & 0 \\ 1 & 0 & 0 & 0 & 0 & 0 & 1 \\ 0 & 0 & 0 & 1 & 0 & 0 & 1 \\ 0 & 0 & 1 & 0 & 1 & 0 & 0 \\ 0 & 0 & 0 & 1 & 0 & 1 & 0 \\ 1 & 0 & 0 & 0 & 1 & 0 & 1 \\ 0 & 1 & 1 & 0 & 0 & 1 & 0\end{matrix} ] ) = [ \begin{matrix}2 & - 1 & 0 & 0 & 0 & - 1 & 0 \\ - 1 & 2 & 0 & 0 & 0 & 0 & - 1 \\ 0 & 0 & 2 & - 1 & 0 & 0 & - 1 \\ 0 & 0 & - 1 & 2 & - 1 & 0 & 0 \\ 0 & 0 & 0 & - 1 & 2 & - 1 & 0 \\ - 1 & 0 & 0 & 0 & - 1 & 3 & - 1 \\ 0 & - 1 & - 1 & 0 & 0 & - 1 & 3\end{matrix} ]$$

The algebraic connectivity of this graph is 0.7530. The Fiedler vector is [−0.4816, −0.4816,0.3333,0.5345,0.3333, −0.1189, −0.1189].

In step 15, the design is validated. Step 15 comprises the computer-implemented steps of validating the spatial locations of the data forwarding device, the connection information and the interconnection information by emulating or simulating the application control network based on an application control plan. The application control plan specifies interaction between the application devices. For example, the resultant network topology or topologies may be entered into a network emulator such as Mininet. A network topology for Mininet would typically be drawn manually in Miniedit. In this case, the network topology, i.e. the output locations of the data forwarding devices and the connection information, have been automatically generated in steps 12 to 14. Step 15 may comprise exporting the automatically generated network topology in a format that can be read by Mininet.

In Mininet, normal computer programs that generate traffic may be started in order to study the behavior of the network topology. Unlike a simulator, Mininet doesn't have a strong notion of virtual time. This means that timing measurements will be based on real time, and that faster-than-real-time results cannot easily be emulated. If the control system 21 is software defined, this control system 21 may be used to generate traffic for Mininet by having the control system 21 execute the application control plan using test scenarios. Every application device can be selected and specific values can be set for the test scenarios.

The emulated application control network's behavior can then be verified, including validating if there is always a network path in time for every application control scene in the application control plan. Step 15 may involve analyzing the output generated by Mininet and if necessary, either automatically adapting the network topology or provide feedback to allow someone to manually adapt the network topology. If necessary, step 12 may be performed again after step 15. Analyzing the output generated by Mininet may comprise estimating the power consumed by the data forwarding devices and/or the end nodes and/or the control system, in any combination, so as to lower overall power consumption of the application network.

Step 15 may further comprise the computer-implemented steps of comparing the automatically generated network topology of FIGS. 5 and 16 with a second (for example manually created) network topology and analyzing differences between the automatically generated network topology and the second network topology. This may involve inspecting differences between the automatically generated network topology and the alternative design, such as cost differences. These cost differences may include, for example, overall cost, number of components, estimated installation time (divided by for example laying cables, connecting connectors to cables, fixing data forwarding devices to ceilings or in cabinets, breaching walls, installing cable trays, etc.) and/or expected energy usage. Since the application control plan is used directly, these cost differences can be estimated relatively accurately. In step 12, the application control plan was not used directly to determine which costs to take into account. Instead, generalized information derived from the application control plan, such as whether an application device needs to operate 12 hours or 24 hours per day and/or which days an application device needs to operate, was used in step 12.

If the automatically generated network topology is accepted, i.e. if step 12 does not need to be repeated, the connection information is output in human readable form to allow an installer to place the data forwarding devices at the output locations in step 3, connect connecting the data forwarding devices and the application devices according to the connection information in step 5, and interconnect the data forwarding devices according to the interconnection information in step 7. To configure a programmable network infrastructure such as SDN networks, part of the connection information can be output in machine readable form to feed the automatic setting of configuration details in the network topology. As an example, unused ports on the data forwarding devices that were planned for future use can be blocked to prevent misuse, traffic budgets can be set, preferred data routes for certain periods based on expected connectivity can be programmed and so on.

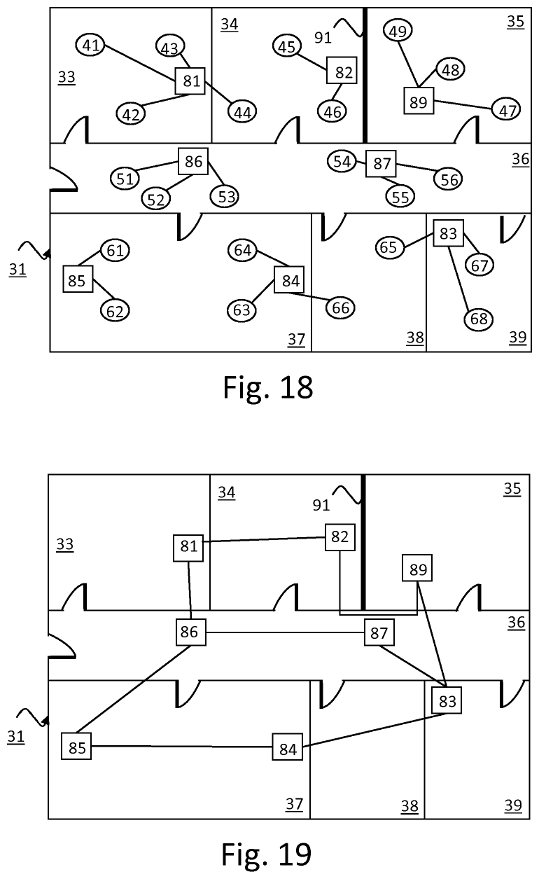

FIGS. 18 and 19 illustrate how the cost of establishing a wired connection between devices through a wall can influence the automatically generated network topology. FIG. 18 shows the application devices 41-68 of FIG. 3. Some of the application devices have been assigned to different data forwarding devices than in FIG. 5. On the floor depicted in FIG. 5, cable trays allowed wired connections to be established through all internal walls via cable trays without much additional cost. On the floor depicted in FIG. 18, the cost of establishing a wired connection between offices 34 and 35 through a wall 91 is high, e.g. because the wall is made from glass and there is no way to avoid the wall without establishing the wired connection via the hallway 36.

In the application control network depicted in FIG. 18, an additional data forwarding device 89 is located in the office 35. Although this means the cost of purchasing, renting or leasing data forwarding devices increases, this is, at least in this case, cheaper than establishing wired connections between application devices 48 and 49 on one hand and data forwarding device 82 on the other hand. Like in the network topology of FIG. 14, a ring topology is used for interconnecting the data forwarding devices 81-87 and 89 in FIG. 19. Additional interconnections have been added between data forwarding devices to increase the robustness of the application control network.

Because of the presence of the wall 19, a cable between data forwarding devices 82 and 89 would have to be longer than without this wall, as shown in FIG. 19. Thus, the length of the cables may depend on the number and type of walls present. The length of the cables between data forwarding devices may be taken into account in step 13 by applying a weighting matrix to the adjacency matrix (A). Step 13 would thus involve increasing the algebraic connectivity of a weighted graph. The weighting matrix may reflect the cable lengths or the costs of the interconnections in general, for example. The topology depicted in FIG. 19 results from applying such a weighting matrix to the adjacency matrix.

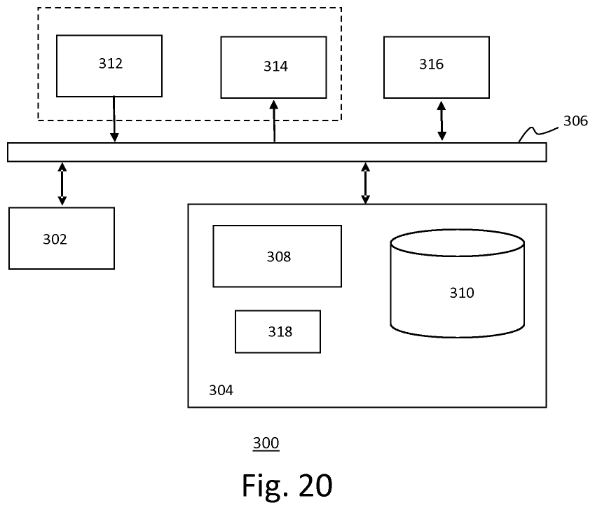

FIG. 20 depicts a block diagram illustrating an exemplary data processing system that may perform step 1 of the method as described with reference to FIGS. 1, 10, 12, and 13.

As shown in FIG. 20, the data processing system 300 may include at least one processor 302 coupled to memory elements 304 through a system bus 306. As such, the data processing system may store program code within memory elements 304. Further, the processor 302 may execute the program code accessed from the memory elements 304 via a system bus 306. In one aspect, the data processing system may be implemented as a computer that is suitable for storing and/or executing program code. It should be appreciated, however, that the data processing system 300 may be implemented in the form of any system including a processor and a memory that is capable of performing the functions described within this specification.

The memory elements 304 may include one or more physical memory devices such as, for example, local memory 308 and one or more bulk storage devices 310. The local memory may refer to random access memory or other non-persistent memory device(s) generally used during actual execution of the program code. A bulk storage device may be implemented as a hard drive or other persistent data storage device. The processing system 300 may also include one or more cache memories (not shown) that provide temporary storage of at least some program code in order to reduce the quantity of times program code must be retrieved from the bulk storage device 310 during execution.

Input/output (I/O) devices depicted as an input device 312 and an output device 314 optionally can be coupled to the data processing system. Examples of input devices may include, but are not limited to, a keyboard, a pointing device such as a mouse, or the like. Examples of output devices may include, but are not limited to, a monitor or a display, speakers, or the like. Input and/or output devices may be coupled to the data processing system either directly or through intervening I/O controllers.

In an embodiment, the input and the output devices may be implemented as a combined input/output device (illustrated in FIG. 20 with a dashed line surrounding the input device 312 and the output device 314). An example of such a combined device is a touch sensitive display, also sometimes referred to as a “touch screen display” or simply “touch screen”. In such an embodiment, input to the device may be provided by a movement of a physical object, such as e.g. a stylus or a finger of a user, on or near the touch screen display.

A network adapter 316 may also be coupled to the data processing system to enable it to become coupled to other systems, computer systems, remote network devices, and/or remote storage devices through intervening private or public networks. The network adapter may comprise a data receiver for receiving data that is transmitted by said systems, devices and/or networks to the data processing system 300, and a data transmitter for transmitting data from the data processing system 300 to said systems, devices and/or networks. Modems, cable modems, and Ethernet cards are examples of different types of network adapter that may be used with the data processing system 300.

As pictured in FIG. 20, the memory elements 304 may store an application 318. In various embodiments, the application 318 may be stored in the local memory 308, the one or more bulk storage devices 310, or separate from the local memory and the bulk storage devices. It should be appreciated that the data processing system 300 may further execute an operating system (not shown in FIG. 20) that can facilitate execution of the application 318. The application 318, being implemented in the form of executable program code, can be executed by the data processing system 300, e.g., by the processor 302. Responsive to executing the application, the data processing system 300 may be configured to perform one or more operations or method steps described herein.

Instead of using input device 312 and output device 314, input may be received using the network adapter 316 and output may be provided using the network adapter 316. For example, the data processing system 300 may be a server on the Internet, e.g. in the cloud. In this case, the application 318 might be a software container stored on the Internet, e.g. in the cloud, instead of in the memory elements 304. The software container might be started as a micro service on the data processing system 300 using a hypervisor, for example.

Various embodiments of the invention may be implemented as a program product for use with a computer system, where the program(s) of the program product define functions of the embodiments (including the methods described herein). In one embodiment, the program(s) can be contained on a variety of non-transitory computer-readable storage media, where, as used herein, the expression “non-transitory computer readable storage media” comprises all computer-readable media, with the sole exception being a transitory, propagating signal. In another embodiment, the program(s) can be contained on a variety of transitory computer-readable storage media. Illustrative computer-readable storage media include, but are not limited to: (i) non-writable storage media (e.g., read-only memory devices within a computer such as CD-ROM disks readable by a CD-ROM drive, ROM chips or any type of solid-state non-volatile semiconductor memory) on which information is permanently stored; and (ii) writable storage media (e.g., flash memory, floppy disks within a diskette drive or hard-disk drive or any type of solid-state random-access semiconductor memory) on which alterable information is stored. The computer program may be run on the processor 302 described herein.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of embodiments of the present invention has been presented for purposes of illustration, but is not intended to be exhaustive or limited to the implementations in the form disclosed. Many modifications and variations will be apparent to those of ordinary skill in the art without departing from the scope and spirit of the present invention. The embodiments were chosen and described in order to best explain the principles and some practical applications of the present invention, and to enable others of ordinary skill in the art to understand the present invention for various embodiments with various modifications as are suited to the particular use contemplated.

1. A method of installing an application control network, comprising:
using a computer to read a building plan specifying the preferred spatial location of application devices and an application control plan specifying interaction between said application devices and to determine:
spatial locations of data forwarding devices in a spatial area, connection information indicating how application devices and said data forwarding devices should be connected by cables and
interconnection information indicating how said data forwarding devices should be interconnected by cables by determining which of said application devices to connect to the same data forwarding device while taking into account a plurality of weighted criteria, at least one of said criteria specifying spatial locations of said application devices in said spatial area and at least one of said criteria relating to connectivity requirements of said application devices;
placing said data forwarding devices at said determined spatial locations of said data forwarding devices;
connecting said data forwarding devices and said application devices according to said determined connection information; and
interconnecting said data forwarding devices according to said determined interconnection information.

2. A method as claimed in claim 1, wherein aspects of the building structure relevant to said spatial area are also taken into account when determining which of said application devices to connect to the same data forwarding device.

3. A method as claimed in claim 1, wherein one or more of said criteria influence capital expenditure and/or one or more of said criteria influence operational expenditure.

4. A method as claimed in claim 3, wherein at least one of said one or more criteria influencing operational expenditure represents a time period in which an application device is likely to communicate data.

5. A method as claimed in claim wherein at least one of said one or more criteria influencing capital expenditure influences costs of said data forwarding devices and/or costs of connecting said application devices and said data forwarding devices.

6. A method as claimed in claim 1, further comprising using said computer to determine a graph of first interconnections between a first group of data forwarding devices, analyze said graph and add at least one further interconnection to said first interconnections based on said analysis.

7. A method as claimed in claim 6, further comprising adding at least one further data forwarding device to said group of data forwarding devices.

8. A method as claimed in claim 6, wherein analyzing said graph comprises determining how to improve a metric of the algebraic connectivity of said graph.

9. A method as claimed in claim 8, wherein analyzing said graph comprises determining a Fiedler vector of said graph, said Fiedler vector comprising a value for each of said data forwarding devices, and determining which data forwarding devices represented in said graph should be connected to improve said metric of said algebraic connectivity of said graph based on the differences between said values in said Fiedler vector.

10. A method as claimed in claim 9, wherein determining which data forwarding devices represented in said graph should be connected to improve said metric of said algebraic connectivity of said graph comprises determining which data forwarding devices have at least one network port available and determining for which two of said determined data forwarding devices a squared difference in corresponding values in said Fiedler vector is largest.

11. A method as claimed in claim 1, further comprising the computer-implemented steps of validating said spatial locations of said data forwarding device, said connection information and said interconnection information by emulating or simulating said application control network based on the application control plan.

12. A method as claimed in claim 1, wherein said application devices comprise sensors and actuators.

13. A method as claimed in claim 1, further comprising the computer-implemented steps of comparing a first network topology with a second network topology, said first network topology comprising said spatial locations of said data forwarding devices, said connection information and said interconnection information, and analyzing differences between said first network topology and said second network topology.

14. A method as claimed in claim 1, wherein which of said application devices communicates with which other one or more of said application devices is also taken into account when determining which of said application devices to connect to the same data forwarding device.

15. A computer program or suite of computer programs comprising at least one software code portion or a computer program product storing at least one software code portion, the software code portion, when run on a computer system, being configured for enabling the method of claim 1.
